(19) United States
(12) Patent Application Publication
(10) Pub. No.: US 2003/0155860 A1
(43) Pub. Date: Aug. 21, 2003

(54) Active matrix type organic electroluminescent display and method of manufacturing the same

(75) Inventors: Beom-Rak Choi, Seoul (KR); Joon-Hoo Choi, Seoul (KR)

Correspondence Address: Frank Chau, F. CHAU & ASSOCIATES, LLP, Suite 501, 1900 Hempstead Turnpike, East Meadow, NY, 11554, US

(73) Assignee: Samsung Electronics Co., Ltd.

(21) Appl. No.: 10/364,035

(22) Filed: Feb. 11, 2003

(30) Foreign Application Priority Data
Feb. 20, 2002 (KR) 2002-9071

(51) Int. Cl. H05B 33/00

(52) U.S. Cl. 313/498

(57) ABSTRACT

Disclosed is an active matrix type organic electroluminescent display and method of manufacturing the same. A black matrix is formed on substantially an entire surface of a substrate except for a portion on which a pixel electrode region is formed. The substrate includes metal interconnections for driving thin film transistors, a pixel electrode connected with the thin film transistors and an organic electroluminescent layer formed on the pixel electrode. By the above structure, reflection of an external light from a non-luminescent region except for the pixel electrode is minimized to thereby obtain a high contrast ratio.

### BACKGROUND

1. Field of the Invention

The present invention relates to an active matrix type organic electroluminescent display (AMOLED) and a method of manufacturing the same, and more particularly, to an AMOLED and a method of manufacturing the same for decreasing reflection of light from a display screen to thereby obtain a high contrast ratio.

2. Discussion of Related Art

In today's information society, electronic display devices are widely used for businesses, industries and homes.

Electronic display devices can be categorized into an emissive display device and a non-emissive display device. The emissive display device displays light information signals using a light emission phenomena and the non-emissive display device displays the light information signals by reflection, scattering, or interference of light. The emissive display device includes a cathode ray tube (CRT), a plasma display panel (PDP), a light emitting diode (LED), and an electroluminescent display (ELD). The emissive display device is called an active display device. Also, the non-emissive display device, called a passive display device, includes a liquid crystal display (LCD), an electrochemical display (ECD), and an electrophoretic image display (EPID).

The CRT has been the most widely used as television receivers or monitors of computers. The CRT displays a high quality image at a relatively low manufacturing cost. Disadvantages of the CRT include its heavy weight, large volume and high power consumption.

Recently, flat panel displays have become increasingly popular. Flat panel displays have excellent characteristics, for example, thin in thickness, light weight, low driving voltage, and low power consumption. Such flat panel display devices can be manufactured according to the rapidly improved semiconductor technology.

An electroluminescent (EL) element has been given much attention by interested users. The EL element is generally divided into an inorganic and an organic type depending on materials used therefor.

The inorganic EL element is a device in which a high electric field is applied to a light emitting part and electrons are accelerated in an applied high electric field to collide with a central region of the light emitting part, so that the light emitting part is excited to thereby emit light.

The organic EL element is a device in which electrons and holes are injected into a light emitting part from a cathode and an anode, respectively, and injected electrons and holes are combined with each other to generate excitons, thereby emitting light when these excitons transition from an excited state to a base state.

The inorganic EL element needs a high driving voltage of 100-200 V, whereas the organic EL element operates at a low voltage of 5-20 V. Also, the organic EL element has superior properties such as wide viewing angle, high response speed, high contrast and the like.

The organic EL elements can be applied to both of an active matrix type display device and a passive matrix type display device. The active matrix organic EL display device is a display device that drives independently each of the organic EL elements corresponding to a plurality of pixels using switching elements such as a thin film transistor. The organic EL display device is also referred to as an organic electroluminescent display (OELD) or an organic light emitting device (OLED). Hereinafter, the active matrix organic EL display device is referred to as AMOLED.

FIG. 1 is a cross-sectional view of a conventional AMOLED. Referring to FIG. 1, a blocking layer 12 comprised of silicon oxide is formed on an insulating substrate 10 made of glass, quartz, sapphire or the like. The blocking layer 12 can be omitted but is preferably used to prevent various impurities contained in the substrate 10 from being penetrated into a silicon film during a subsequent process of crystallizing an amorphous silicon layer.

On the blocking layer 12, there is formed a thin film transistor (TFT) 30 including an active pattern 14, a gate insulating layer 16, a gate electrode 18, an insulating interlayer 20, and source/drain electrodes 26 and 28.

A passivation layer 32 is formed on the entire surface of the substrate 10 including the TFT 30. On the passivation layer 32, there is formed a pixel electrode 36 connected to any one of the source/drain electrodes 26 and 28 through a via hole 34. The pixel electrode 36 that comprises a transparent conductive film of indium tin oxide (ITO) or indium zinc oxide (IZO) is provided as an anode of an organic EL element 50.

On the passivation film 32 and the pixel electrode 36, there is formed an organic insulating layer 40 having an opening 42 exposing a portion of the pixel electrode 36. An organic EL layer 44 is formed on the opening 42. As a cathode of the organic EL element 50, a metal electrode 46 for a rear luminescence is formed on the organic EL layer 44.

According to the above described conventional AMOLED, light generated from the organic EL element 50 is emitted to the outside through the underlying substrate on which the TFT 30 is formed. Since the substrate on which the TFT 30 is formed is arranged toward a display screen, an external natural light incident into the display screen is reflected from metal behind the screen, such as the interconnections for driving the TFT 30 and the metal electrode 46 of the organic EL element 50. The reflected light interferes the view toward the screen by a user. And, since the reflected light also exists during an OFF-state, it becomes difficult to realize the black state.

One proposal to solve these problems is by using a circular polarizing plate. However, the circular polarizing plate itself blocks a portion of the light emitted from the organic EL layer, decreasing luminance by about 60%. Another proposed method is by using a cathode electrode which is formed with a material having a low reflectivity. However, only about 50% of the emitted light is emitted to the outside. Further, light reflected from the TFT and the metal interconnections still exists.

As described above, since an AMOLED has a low aperture ratio and a large number of metal interconnections, a non-luminescent area is mostly occupied by the metal interconnections.

A need therefore exists for an AMOLED capable of obtaining a high contrast ratio by decreasing an amount of light reflected from a non-luminescent area.

### SUMMARY OF THE INVENTION

According to an embodiment of the present invention, an AMOLED is provided which comprises a substrate including a TFT, metal interconnections for driving the TFT, a pixel electrode connected to the TFT, an organic EL layer formed on the pixel electrode, and a black matrix formed on substantially the entire surface of the substrate except for a portion on which the pixel electrode is formed.

Further, on the black matrix, there is formed a TFT including an active pattern, a gate electrode, and source/drain electrodes. A passivation film is formed on the TFT, the black matrix, and the substrate. A pixel electrode is formed on the passivation film to be connected to the TFT. An organic EL layer is formed on the pixel electrode.

According to another embodiment of the present invention, a method is provided for manufacturing an AMOLED, the method comprising the steps of forming a black matrix on an entire surface of a substrate except for a pixel electrode region; forming a TFT on a black matrix, the TFT including an active pattern, a gate electrode, and source/drain electrodes; forming a passivation film on the TFT, the black matrix, and the substrate; forming a pixel electrode on the passivation film to connect with the TFT; and forming an organic EL layer on the pixel electrode.

With the above embodiments, a black matrix having a low reflectivity is formed on the entire surface of the substrate except for the pixel electrode region, thereby preventing an external light from being reflected at a region except for the pixel electrode region, i.e., a non-luminescent region.

### BRIEF DESCRIPTION OF THE DRAWINGS

The present invention will become more apparent by describing in detail exemplary embodiments thereof with reference to the attached drawings in which:

FIG. 1 is a cross-sectional view of a conventional AMOLED;

FIG. 2 is a cross-sectional view of an AMOLED in accordance with an embodiment of the present invention;

FIGS. 3A to 3E are cross-sectional views for illustrating steps of a method for manufacturing the AMOLED shown in FIG. 2;

FIG. 4 is a plan view of an AMOLED in accordance with an embodiment of the present invention; and

FIG. 5 is a plan view of an AMOLED in accordance with an embodiment of the present invention.

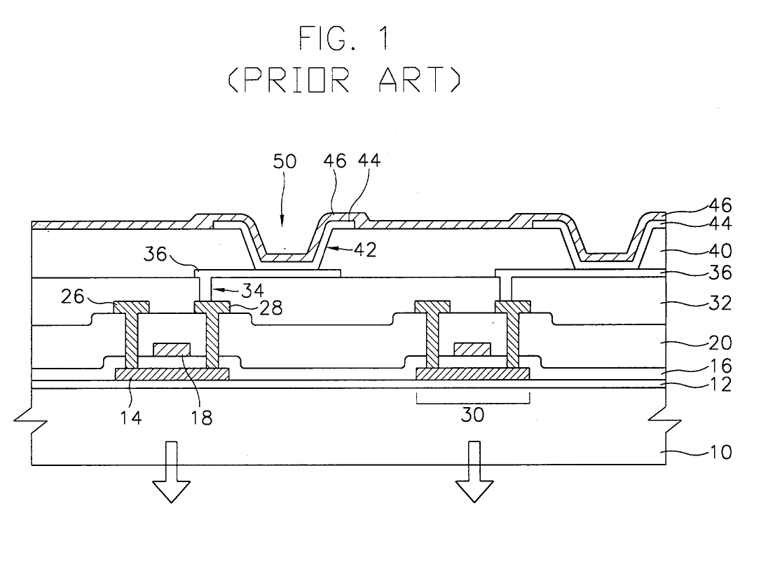

### DETAILED DESCRIPTION OF PREFERRED EMBODIMENTS

Now, preferred embodiments of the present invention will be described in detail with reference to the attached drawings.

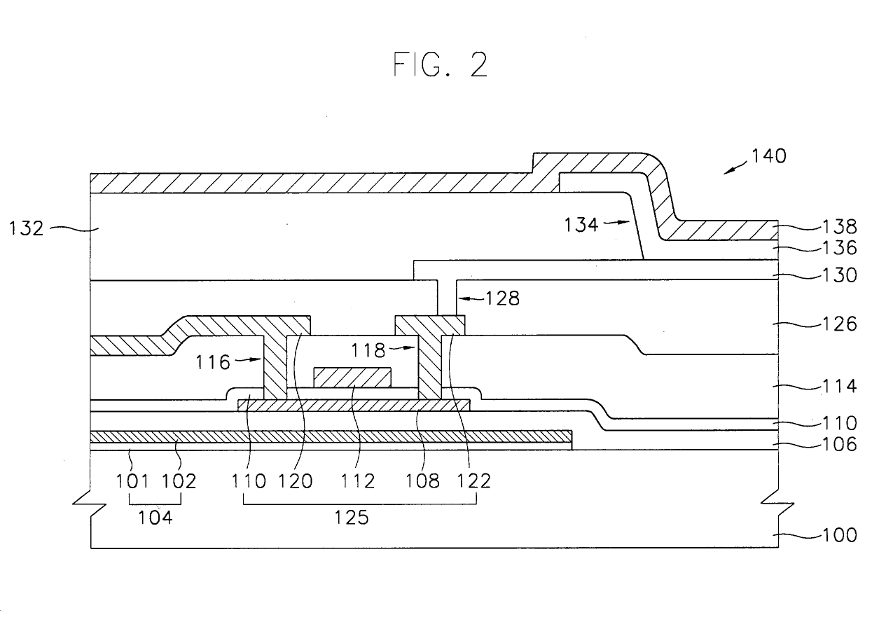

FIG. 2 is a cross-sectional view of an AMOLED in accordance with an embodiment of the present invention. Referring to FIG. 2, a black matrix 104 is formed on an entire surface of an insulating substrate 100 except for a region on which a pixel electrode is formed. The insulating substrate 100 comprises glass, quartz or sapphire. To prevent reflection of an external light, the black matrix 104 should be made of a material having a low reflectivity of less than about 5%, preferably between about 3% and about 4%.

Preferably, the black matrix 104 is formed in a stack structure having a metal oxide layer 101 of CrOₓ, NiOₓ or FeOₓ and an-overlying metal layer 102 of Cr, Ni or Fe. In typical, the metal oxide layer 101 of CrOₓ, NiOₓ or FeOₓ transmits the light of about 50% and reflects the other amount of the light. So, if the metal layer 102 having a relatively high reflectivity is stacked on the metal oxide layer 101, the destructive interference of the light incident upon the black matrix 104 occurs to decrease the reflectivity. Alternatively, the black matrix 104 may be formed of a single layer consisting of an opaque material.

On the entire surface of the substrate 100 including the black matrix 104, there is formed a thermal diffusion-barrier layer 106 that comprises silicon oxide. The thermal diffusion-barrier layer 106 functions to prevent heat from being emitted from the metal layer 102 of the black matrix 104 during a subsequent crystallization of an active layer of a thin film transistor.

On the thermal diffusion-barrier layer 106, there is formed a thin film transistor 125 including an active pattern 108, a gate insulating layer 110, a gate electrode 112, an insulating interlayer 114, and source/drain electrodes 120 and 122. The source and drain electrodes 120 and 122 are-respectively connected to source and drain regions (not shown) formed in the active pattern 108 through contact holes 116 and 118. Preferably, the active pattern 108 is formed at a region that is spaced apart by 1 μm or more from an edge of the black matrix 104 to obtain uniform TFT characteristics.

On the source and drain electrodes 120 and 122 and the insulating interlayer 114, there is formed a passivation layer 126 made of an inorganic insulating material such as silicon nitride. On the passivation film layer 126, a pixel electrode 130 is formed to be connected to any one of the source electrode 120 and the drain electrode 122 through a via hole 128, for example, the drain electrode 122 through a via hole 128. The pixel electrode 130 made of a transparent conductive film such as ITO or IZO is provided as an anode of an organic EL element 140.

On the passivation layer 126 and the pixel electrode 130, an organic insulating layer 132 having an opening 134 exposing a part of the pixel electrode 130 is formed. An organic EL layer 136 is formed on the opening 134. As a cathode of the organic EL element 140, a metal electrode 138 for the rear luminescence is formed on the organic EL layer 136.

Hereinafter, there is described a method for manufacturing an AMOLED having the aforementioned structure.

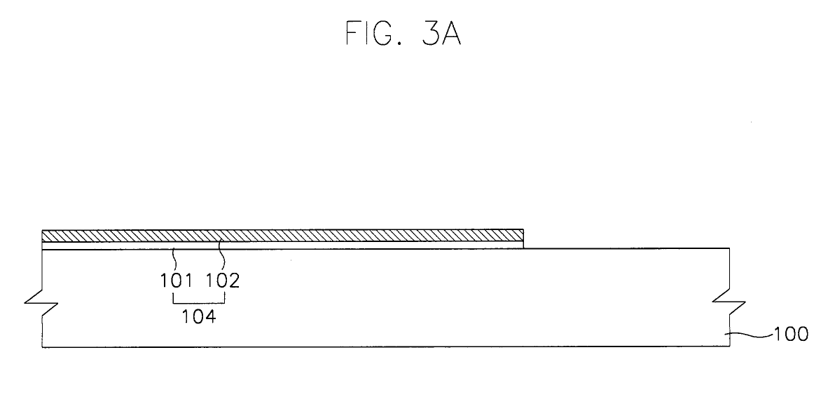

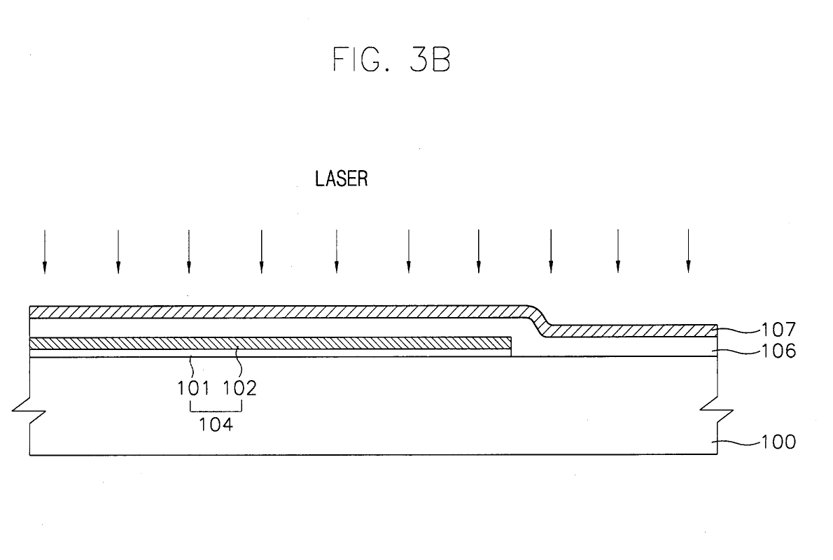

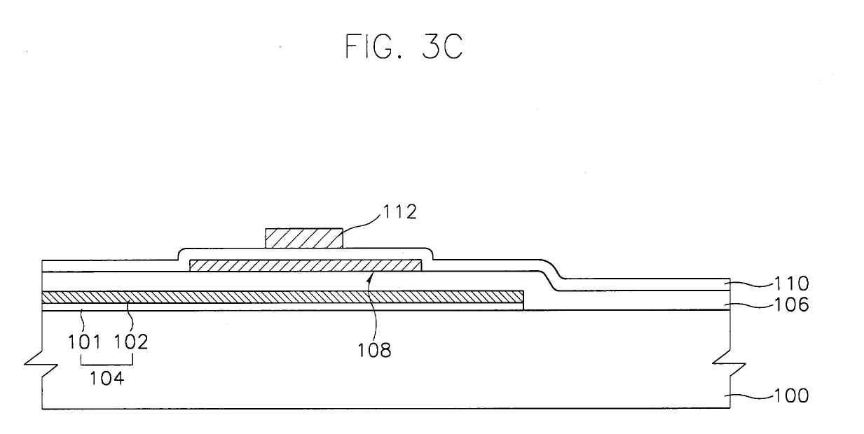

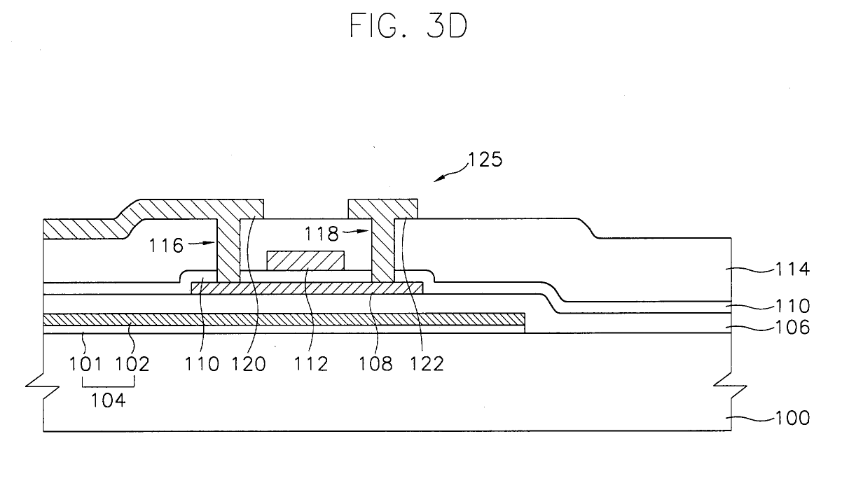

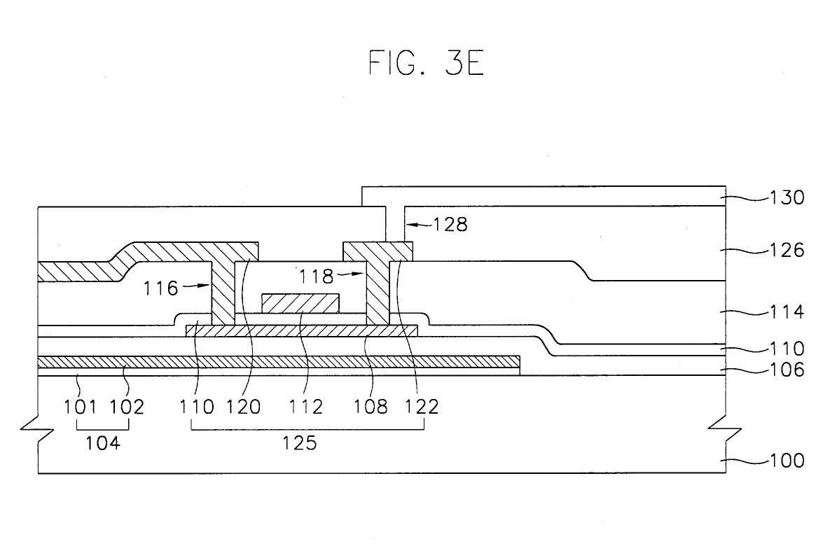

FIGS. 3A to 3E are cross-sectional views for illustrating a method of manufacturing the AMOLED shown in FIG. 2. Referring to FIG. 3A, a metal oxide layer 101 made of CrOₓ, NiOₓ, or FeOₓ is deposited to have a thickness of about 500 Å on an insulating substrate 100 such as glass, quartz or sapphire. Then, a metal layer 102 having a low reflectivity, e.g., Cr, Ni, or Fe, is deposited to have a thickness of about 1,000 Å on the metal oxide layer 101.

Thereafter, the metal layer 102 and the metal oxide layer 101 are patterned using a photolithography process, so that a black matrix 104 is formed on the entire surface of the substrate 100 except for a region on which a pixel electrode will be formed.

Referring to FIG. 3B, on the entire surface of the substrate 100 including the black matrix 104, silicon oxide is deposited to have a thickness of approximately 2,000 Å by a plasma-enhanced chemical vapor deposition (PECVD) process for thereby forming a thermal diffusion-barrier layer 106. The thermal diffusion-barrier layer 106 functions to prevent heat from being irradiated during a subsequent process for crystallizing an active layer.

On the thermal diffusion-barrier layer 106, an amorphous silicon film is deposited to have a thickness of approximately 500 Å by a low pressure chemical vapor deposition (LPCVD) process or PECVD process for forming an active layer 107. Then, the active layer 107 is laser-annealed, so that the active layer 107 of amorphous silicon is crystallized into the active layer of polycrystalline silicon. The laser annealing is performed using a high energy capable of compensating for heat loss through the black matrix 104, for example, 440-450 mJ/cm², so that a polycrystalline film having the same size of grains can be obtained.

Referring to FIG. 3C, a polycrystalline silicon active layer 107 is patterned using a photolithography process to form an active pattern 108 on a TFT region of a unit pixel. The polycrystalline silicon active layer 107 has different sizes of grains at an edge portion and a central portion of the black matrix 104, and it has a uniform size of grains at a region that is spaced apart by about 1 μm or more from the edge portion of the black matrix 104. Accordingly, if the active pattern 108 is formed at the region that is spaced apart by about 1 μm or more from the edge portion of the black matrix 104, uniform TFT characteristics can be obtained.

Thereafter, on the active pattern 108 and the thermal diffusion-barrier layer 106, a silicon oxide film is deposited to have a thickness of about 1,000-2,000 Å by the PECVD process for forming a gate insulating layer 110. A gate layer, e.g., an AlNd, is deposited on the gate insulating layer 110 to have a thickness of approximately 3,000 Å by a sputtering method, and is then patterned by a photolithography process. As a result, a gate line (not shown) extending in a first direction and a gate electrode 112 of the TFT branched from the gate line are formed.

Here, impurity ions are implanted using a photo mask used for patterning the gate layer to thereby form source/drain regions (not shown) in the surface at both sides of the active pattern 108.

Referring to FIG. 3D, laser or furnace annealing is performed to activate doped ions of the source/drain regions and to cure damaged portions of the silicon layer. Then, a silicon nitride film is deposited to have a thickness of approximately 800 Å on the entire surface of the resultant structure for forming an insulating interlayer 114.

Thereafter, the insulating interlayer 114 is etched away using a photolithography process to form contact holes 116 and 118 exposing the source/drain regions. A data layer, e.g., MoW or AlNd, is deposited on the insulating interlayer 114 and the contact holes 116 and 118 to have a thickness of approximately 3,000-6,000 Å, and then, patterned by a photolithography process. By doing so, there are formed a data line (not shown) extending in a second direction perpendicular to the first direction, a direct current signal line (Vdd), and source/drain electrodes 120 and 122 respectively connected to the source/drain regions through the contact holes 116 and 118.

Through the aforementioned processes, there is formed a TFT 125 including a active pattern 108, a gate insulating layer 110, a gate electrode 112, and source/drain electrodes 120 and 122 on the substrate 100 having a black matrix 104.

Referring to FIG. 3E, on the insulating interlayer 114 including the TFT 125, a silicon nitride film is deposited to have a thickness of approximately 2,000-3,000 Å for forming a passivation layer 126. Then, the passivation layer 126 is etched away using a photolithography process to form a via hole 128 exposing any one of the source electrode 120 and the drain electrode 122.

A transparent conductive layer such as ITO or IZO is deposited on the passivation layer 126 and the via hole 128, and then, patterned by a photolithography process to form a pixel electrode 130 connected to the drain electrode 122 of the TFT 125 through the via hole 128. The pixel electrode 130 is provided as an anode of an organic EL element 140.

Referring again to FIG. 2, an organic insulating layer 132 is formed on the passivation layer 126 including the pixel electrode 130 and then, patterned by an exposure and development processes to form an opening 134 exposing a portion of the pixel electrode 130.

Thereafter, a hole transfer layer (HTL: not shown), an organic EL layer 136, an electron transfer layer (ETL: not shown) are sequentially formed on the opening 134, and then, a metal electrode serving as a cathode of the organic EL element 140 is formed on the entire surface of the resultant structure.

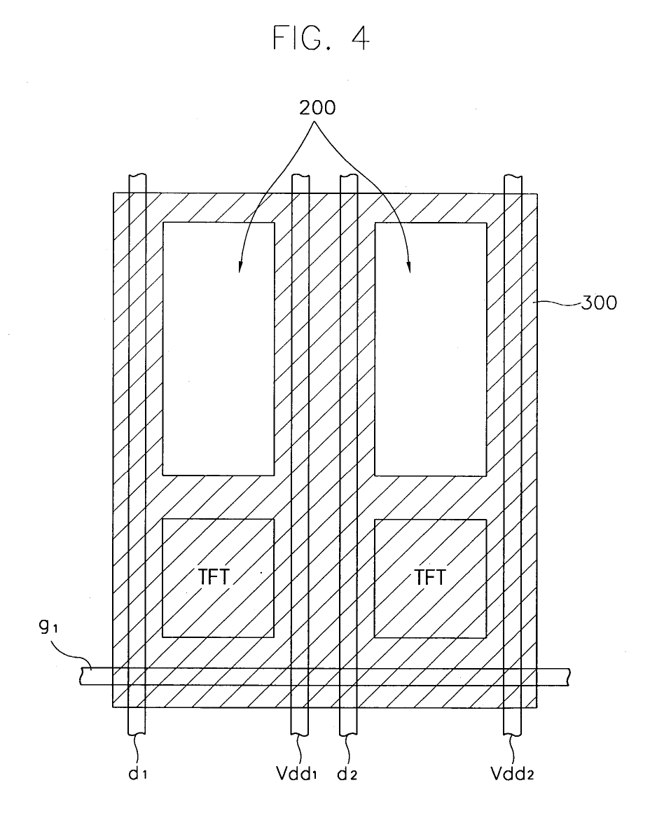

FIG. 4 is a plan view of an AMOLED according to an embodiment of the present invention. Referring to FIG. 4, a pixel including two TFTs, one capacitor (not shown) and an organic EL element is arranged to have a pixel region defined by three interconnection lines of a gate line g1, a data line d1, and a power supply line Vdd1. The power supply line Vdd1 supplies a reference voltage necessary for driving a drive TFT by applying a common voltage Vdd to all pixels.

Thus, in an AMOLED having the pixel region defined through the three interconnection lines, pixel electrodes 200 occupy an area of about 40% in an overall panel area. Accordingly, a black matrix 300 is formed at an overall region except for the pixel electrode region 200, i.e., below the TFTs and the three interconnection lines g1, d1, and Vdd1, thereby minimizing reflection of an external light from a non-luminescent region except for the pixel electrode region 200.

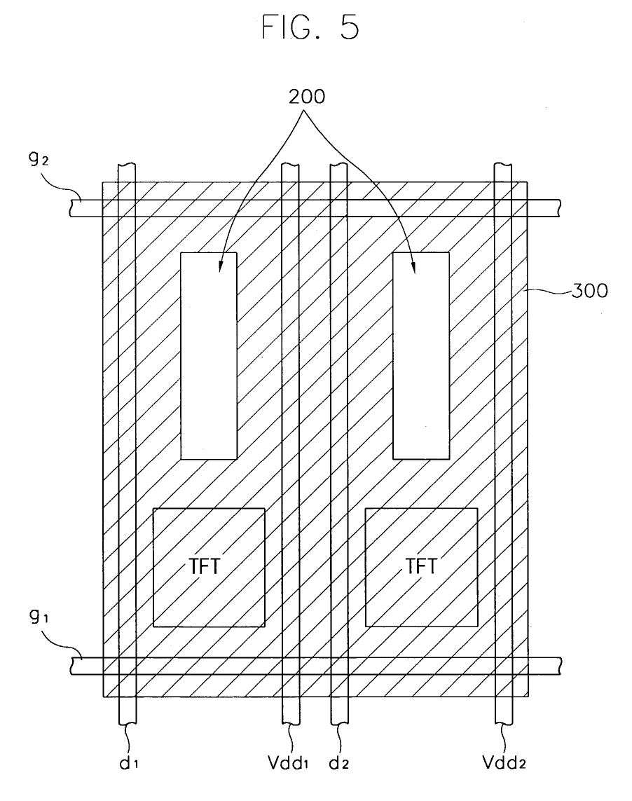

FIG. 5 is a plan view of an AMOLED according to another embodiment of the present invention. Referring to FIG. 5, a pixel including three TFTS, at least one capacitor (not shown) and an organic EL element is arranged to have a pixel region defined by four interconnection lines of two gate lines g1 and g2, a data line d1, and a power supply line Vdd1.

In an AMOLED having a pixel region defined through the four interconnection lines, an area occupied by a pixel electrode 200 decreases and thus, the pixel electrode region 200 occupies an area of about 20% or so in an overall panel area. Accordingly, a black matrix 300 is formed at an overall region except for the pixel electrode region 200, i.e., below the TFTs and the four interconnection lines g1, g2, d1, and Vdd1, thereby minimizing the reflection of an external light from a non-luminescent region except for the pixel electrode region 200.

Although the above embodiments show examples in which a black matrix is formed below thin film transistors and metal interconnections, it is apparent that a pixel electrode can be made of a low reflection metal to minimize reflective light. However, such a configuration may cause a drawback that 50% or more of the light irradiated from an organic EL layer is wasted.

As described above, according to preferred embodiments of the present invention, a black matrix having a low reflectivity is formed on substantially the entire surface of a substrate except for the pixel electrode region, so that the reflection of an external light from a region non-luminescent except for the pixel electrodes is minimized, thereby obtaining a high contrast ratio. Accordingly, with these preferred embodiments, it is possible to realize nearly complete black in an OFF-state even in case that the aperture ratio is low. In addition, loss of the light irradiated from an organic EL layer can be minimized. Further, a high price polarizing plate can be eliminated, resulting in enhanced luminance and reduced manufacturing costs.

While preferred embodiments of the present invention have been described in detail, it has to be understood that various changes, substitutions, and alterations can be made hereto without departing from the spirit and scope of the invention as defined by the appended claims.

What is claimed is:

1. An active matrix type organic electroluminescent display comprising:
a substrate including a thin film transistor, metal interconnections for driving the thin film transistor, a pixel electrode connected with the thin film transistor, and an organic electroluminescent layer formed on the pixel electrode; and
a black matrix formed on substantially an entire surface of the substrate except for a portion on which the pixel electrode region is formed.

2. The active matrix type organic electroluminescent display as claimed in claim 1, wherein the black matrix is formed below the thin film transistor and the metal interconnections.

3. The active matrix type organic electroluminescent display as claimed in claim 2, further comprising a thermal diffusion-barrier layer formed on the black matrix.

4. The active matrix type organic electroluminescent display as claimed in claim 1, wherein the black matrix includes a metal oxide layer and a metal layer stacked on the metal oxide layer.

5. The active matrix type organic electroluminescent display as claimed in claim 4, wherein the black matrix comprises any one selected from the group consisting of chromium oxide/chromium, nickel oxide/nickel, and iron oxide/iron.

6. An active matrix type organic electroluminescent display comprising:
a substrate;
a black matrix formed on substantially an entire surface of the substrate;
a thin film transistor formed on the black matrix and having an active pattern, a gate electrode, and source/drain electrodes;
a passivation layer formed on the thin film transistor, the black matrix, and the substrate;
a pixel electrode formed on the passivation layer, the pixel electrode being connected with the thin film transistor; and
an organic electroluminescent layer formed on the pixel electrode.

7. The active matrix type organic electroluminescent display as claimed in claim 6, wherein the black matrix is formed on substantially the entire surface of the substrate except for a pixel electrode region.

8. The active matrix type organic electroluminescent display as claimed in claim 7, further comprising a thermal diffusion-barrier layer formed between the black matrix and the thin film transistor.

9. The active matrix type organic electroluminescent display as claimed in claim 7, wherein the active pattern of the thin film transistor is formed at a region that is spaced apart by no less than about 1 μm from an edge of the black matrix.

10. A method of manufacturing an active matrix type organic electroluminescent display, the method comprising the steps of:
forming a black matrix on substantially an entire surface of a substrate;
forming a thin film transistor on the black matrix and the substrate, the thin film transistor including an active pattern, a gate electrode, and source/drain electrodes;
forming a passivation layer on the thin film transistor, the black matrix, and the substrate;
forming a pixel electrode on the passivation layer to connect with the thin film transistor; and
forming an organic electroluminescent layer on the pixel electrode.

11. The method as claimed in claim 10, wherein the method further comprises forming the black matrix on substantially the entire surface of the substrate except for a pixel electrode region.

12. The method as claimed in claim 11, prior to the step of forming the thin film transistor, further comprising a step of forming a thermal diffusion-barrier layer on the black matrix and the substrate.

13. The method as claimed in claim 11, wherein the step of forming the active pattern of the thin film transistor comprises the steps of:
depositing an active layer on the black matrix and the substrate;
crystallizing the active layer by applying an energy capable of compensating for a heat loss through the black matrix; and
patterning the active layer to form the active pattern at a region that is spaced apart by no less than about 1 μm from an edge of the black matrix.

14. The method as claimed in claim 11, wherein the black matrix comprises a metal oxide layer and a metal layer stacked on the metal oxide layer.

15. The method as claimed in claim 11, wherein the black matrix comprises any one selected from a group consisting of chromium oxide/chromium, nickel oxide/nickel, and iron oxide/iron.

16. An active matrix type organic electroluminescent display comprising:
a substrate including a thin film transistor, metal interconnections for driving the thin film transistor, a pixel electrode connected with the thin film transistor, and an organic electroluminescent layer formed on the pixel electrode; and
a low reflective pattern formed on a surface of the substrate except for a portion on which the pixel electrode region is formed.

17. The active matrix type organic electroluminescent display as claimed in claim 16, wherein the low reflective pattern is a black matrix.

18. The active matrix organic electroluminescent display as claimed in claim 16, wherein the low reflective pattern comprises a material having a low reflectivity of less than about 5%.

19. The active matrix type organic electroluminescent display as claimed in claim 16, wherein the low reflective pattern includes a metal oxide layer and a metal layer stacked on the metal oxide layer.

20 An active matrix type organic electroluminescent display comprising:
a substrate;
a low reflective pattern formed on substantially a surface of the substrate except for a pixel electrode region;
a thin film transistor formed on the low reflective pattern and having an active pattern, a gate electrode, and source/drain electrodes;
a passivation layer formed on the thin film transistor, the low reflective pattern, and the substrate;
a pixel electrode formed on the passivation layer, the pixel electrode being connected with the thin film transistor; and
an organic electroluminescent layer formed on the pixel electrode.

21. The active matrix type organic electroluminescent display as claimed in claim 20, wherein the low reflective pattern comprises a material having a low reflectivity of less than about 5%.

22. A method of manufacturing an active matrix type organic electroluminescent display, the method comprising:
forming a low reflective pattern on substantially a surface of a substrate except for a pixel electrode region;
forming a thin film transistor on the low reflective pattern and the substrate, the thin film transistor including an active pattern, a gate electrode, and source/drain electrodes;
forming a passivation layer on the thin film transistor, the low reflective pattern, and the substrate;
forming a pixel electrode on the passivation layer to connect with the thin film transistor; and
forming an organic electroluminescent layer on the pixel electrode.

23. The method as claimed in claim 22, wherein the low reflective pattern comprises a material having a low reflectivity of less than about 5%.

24. The method as claimed in claim 22, wherein the low reflective pattern comprises a metal oxide layer and a metal layer stacked on the metal oxide layer.
